(19) United States
(12) Patent Application Publication
(10) Pub. No.: US 2023/0253341 A1
(43) Pub. Date: Aug. 10, 2023

(54) CIRCUIT MODULE

(71) Applicant: Murata Manufacturing Co., Ltd., Kyoto (JP)

(72) Inventors: Takahiro KITADUME, Nagaokakyo-shi (JP); Yoshihito OTSUBO, Nagaokakyo-shi (JP); Tadashi NOMURA, Nagaokakyo-shi (JP)

(21) Appl. No.: 18/191,142

(22) Filed: Mar. 28, 2023

Related U.S. Application Data
(63) Continuation of application No. PCT/JP2021/038631, filed on Oct. 19, 2021.

(30) Foreign Application Priority Data
Oct. 22, 2020 (JP) 2020-177529

(51) Int. Cl. H01L 23/552; H01L 23/66; H01L 23/498; H01L 25/16

(52) U.S. Cl. CPC H01L 23/552; H01L 23/66; H01L 23/49811; H01L 25/165; H01L 24/16; H01L 2223/6677; H01L 2924/3025; H01L 2924/14215

(57) ABSTRACT

To provide a circuit module capable of reducing the influence of noise transmitted through a shield film on an inductor mounted on a substrate. A circuit module according to the present disclosure includes a substrate, an inductor mounted on a surface of the substrate, a sealing resin provided on the surface of the substrate and covering the inductor, a conductive shield film covering the sealing resin, and a wire disposed between the inductor on the surface of the substrate and the side film of the shield film. The one end portion of the wire is electrically connected to the side film. The other end portion of the wire is electrically connected to the surface of the substrate. In plan view, an imaginary straight line passing through the one end portion and the other end portion of the wire is inclined with respect to the side film.

### CROSS REFERENCE TO RELATED APPLICATION

This is a continuation of International Application No. PCT/JP2021/038631 filed on Oct. 19, 2021 which claims priority from Japanese Patent Application No. 2020-177529 filed on Oct. 22, 2020. The contents of these applications are incorporated herein by reference in their entireties.

### BACKGROUND OF THE DISCLOSURE

### Field of the Disclosure

The present disclosure relates to a circuit module including a substrate and an inductor mounted on the substrate.

### Description of the Related Art

A circuit module including a substrate and an electronic component mounted on the substrate is known. Examples of the electronic component include a resistor, a capacitor, an inductor, a transistor, and an integrated circuit.

It is known to provide a shield film that shields electromagnetic waves around an electronic component. The shield film reduces entry of an electromagnetic wave from the outside into the electronic component. Furthermore, the shield film reduces leakage of the electromagnetic wave generated in the electronic component to the outside.

Patent Document 1 discloses a semiconductor device including a substrate and a semiconductor element (electronic component) mounted on an upper surface of the substrate, in which the semiconductor element is covered with a conductive shield layer (shield film).

Patent Document 1: JP 2012-160576 A

### BRIEF SUMMARY OF THE DISCLOSURE

In a case where an inductor is mounted on the substrate, the following problems may occur. When current flows through the inductor, a magnetic field is generated in the inductor. On the other hand, when noise generated inside or outside a circuit module is transmitted through a shield film, a magnetic field is generated by an eddy current or the like due to the noise. When lines of magnetic force due to the magnetic field generated in the shield film are coupled with lines of magnetic force due to the magnetic field generated in the inductor, the lines of magnetic force in the inductor fluctuate unexpectedly. Then, characteristics of other electronic components (for example, a low noise amplifier (LNA)) electrically connected to the inductor deteriorate.

Therefore, a possible benefit of the present disclosure is to solve the above problems, and to provide a circuit module capable of reducing the influence of noise transmitted through a shield film on an inductor mounted on a substrate.

In order to achieve the above possible benefit, the present disclosure is configured as follows. A circuit module according to an aspect of the present disclosure includes: a substrate; an inductor mounted on a surface of the substrate; a wiring portion formed on the surface of the substrate; a sealing resin provided on the surface of the substrate and covering the inductor; a conductive shield film covering at least a part of the sealing resin and including a side film extending in a direction intersecting the surface of the substrate; and a conductive member disposed between the inductor and the side film on the surface of the substrate and electrically connected to the side film and the wiring portion, in which a first portion of the conductive member is connected to a facing surface of the side film facing the inductor, a second portion of the conductive member is connected to the surface of the substrate, and in plan view in which the surface of the substrate is viewed along a direction orthogonal to the surface of the substrate, an imaginary straight line passing through the first portion and the second portion of the conductive member is inclined with respect to the facing surface of the side film.

According to the present disclosure, it is possible to reduce the influence of noise transmitted through a shield film on an inductor mounted on a substrate.

### BRIEF DESCRIPTION OF THE SEVERAL VIEWS OF THE DRAWINGS

FIG. 1 is a plan view of a circuit module according to a first embodiment of the present disclosure.

FIG. 2 is a cross-sectional view taken along line A-A in FIG. 1.

FIG. 3 is a perspective view of an inductor.

FIG. 4 is an enlarged view of a portion indicated by a two-dot chain line in FIG. 1.

FIG. 5 is a plan view of a circuit module according to a second embodiment of the present disclosure.

FIG. 6 is a plan view of a circuit module according to a third embodiment of the present disclosure.

FIG. 7 is a plan view of a circuit module according to a fourth embodiment of the present disclosure.

FIG. 8 is a plan view of a circuit module according to a fifth embodiment of the present disclosure.

FIG. 9 is a cross-sectional view taken along the line B-B in FIG. 8.

### DETAILED DESCRIPTION OF THE DISCLOSURE

A circuit module according to an aspect of the present disclosure includes: a substrate; an inductor mounted on a surface of the substrate; a wiring portion formed on the surface of the substrate; a sealing resin provided on the surface of the substrate and covering the inductor; a conductive shield film covering at least a part of the sealing resin and including a side film extending in a direction intersecting the surface of the substrate; and a conductive member disposed between the inductor and the side film on the surface of the substrate and electrically connected to the side film and the wiring portion, in which a first portion of the conductive member is connected to a facing surface of the side film facing the inductor, a second portion of the conductive member is connected to the surface of the substrate, and in plan view in which the surface of the substrate is viewed along a direction orthogonal to the surface of the substrate, an imaginary straight line passing through the first portion and the second portion of the conductive member is inclined with respect to the facing surface of the side film.

According to this configuration, a pseudo inductor is formed by the conductive member, the side film, and the wiring portion. Furthermore, according to this configuration, in plan view, the imaginary straight line passing through the first portion and the second portion of the conductive member is inclined with respect to the facing surface of the side film. That is, the pseudo inductor described above is inclined with respect to the facing surface of the side film. Therefore, the lines of magnetic force generated by the magnetic field due to the noise transmitted through the shield film extend perpendicularly from the facing surface of the side film toward the inductor mounted on the substrate, but are redirected in the pseudo inductor. Accordingly, the redirected lines of magnetic force travel so as to avoid the inductor mounted on the substrate. As a result, coupling between the lines of magnetic force extending from the shield film and the lines of magnetic force generated in the inductor mounted on the substrate is reduced.

The imaginary straight line may not be orthogonal to a winding axis of the inductor. According to this configuration, the direction in which the lines of magnetic force passing through the pseudo inductor formed by the conductive member, the side film, and the wiring portion travel is a direction inclined with respect to the lines of magnetic force due to the magnetic field generated in the inductor mounted on the substrate. Therefore, only a part of vector component decomposed components in the lines of magnetic force passing through the pseudo inductor is coupled with lines of magnetic force generated in the inductor among the lines of magnetic force passing through the pseudo inductor. Therefore, coupling between the lines of magnetic force extending from the shield film and the lines of magnetic force generated in the inductor is reduced.

A circuit module according to an aspect of the present disclosure may further include an electronic component mounted on the substrate and electrically connected to the inductor, in which the electronic component may be located on an opposite side of the conductive member with respect to the inductor in the plan view. According to this configuration, the electronic component is electrically connected to the inductor. Therefore, when the inductor is affected by noise transmitted through the shield film, characteristics of the electronic component may be deteriorated. However, according to this configuration, coupling between the lines of magnetic force extending from the side film and the lines of magnetic force generated in the inductor is reduced. Therefore, deterioration of the characteristics of the electronic component can be suppressed.

The conductive member may be a wire. According to this configuration, the conductive member is a wire. Therefore, a pseudo inductor can be easily formed by the conductive member, the side film, and the wiring portion.

A circuit module according to an aspect of the present disclosure may include a plurality of the conductive members, and in the plan view, a plurality of the conductive members may be arranged side by side along a direction in which the facing surface of the side film extends. According to this configuration, the circuit module includes the plurality of conductive members. Therefore, the lines of magnetic force extending from the side film can be redirected over a wide range.

A plurality of the conductive members may be arranged in parallel or substantially parallel to each other in the plan view. According to this configuration, the lines of magnetic force of the respective conductive members are redirected in the same direction or substantially the same direction. Therefore, for example, it is easy to cope with not arranging an inductor ahead in a traveling direction of the redirected lines of magnetic force. Furthermore, according to this configuration, the plurality of conductive members can be arranged in higher density than in a case where the plurality of conductive members are not arranged in parallel or substantially parallel to each other.

In a direction along the facing surface of the side film and parallel to the surface of the substrate, the second portion of one of the two adjacent conductive members may be located between the first portion and the second portion of the other of the two adjacent conductive members. According to this configuration, when viewed from the facing surface of the side film, boundary portions of the two adjacent conductive members overlap with each other. Therefore, it is possible to increase the possibility that the lines of magnetic force traveling from the facing surfaces of the side films to the boundary portions are redirected by any of the two conductive members.

A plurality of the conductive members may be disposed in a non-facing region not between the inductor and the side film on the surface of the substrate in addition to the facing region between the inductor and the side film on the surface of the substrate, and a distance between the two adjacent conductive members in the facing region may be shorter than a distance between the two adjacent conductive members in the non-facing region.

According to this configuration, the lines of magnetic force from the facing surface of the side film toward the inductor through the non-facing region are smaller than the lines of magnetic force from the facing surface of the side film toward the inductor through the facing region. According to this configuration, it is possible to arrange a large number of conductive members in the facing region where there are many lines of magnetic force toward the inductor. On the other hand, a space occupied by the conductive members on the surface of the substrate can be reduced by reducing the number of conductive members arranged in the non-facing region where the lines of magnetic force toward the inductor are small. As a result, it is possible to increase a space where other members are arranged on the surface of the substrate.

### First Embodiment

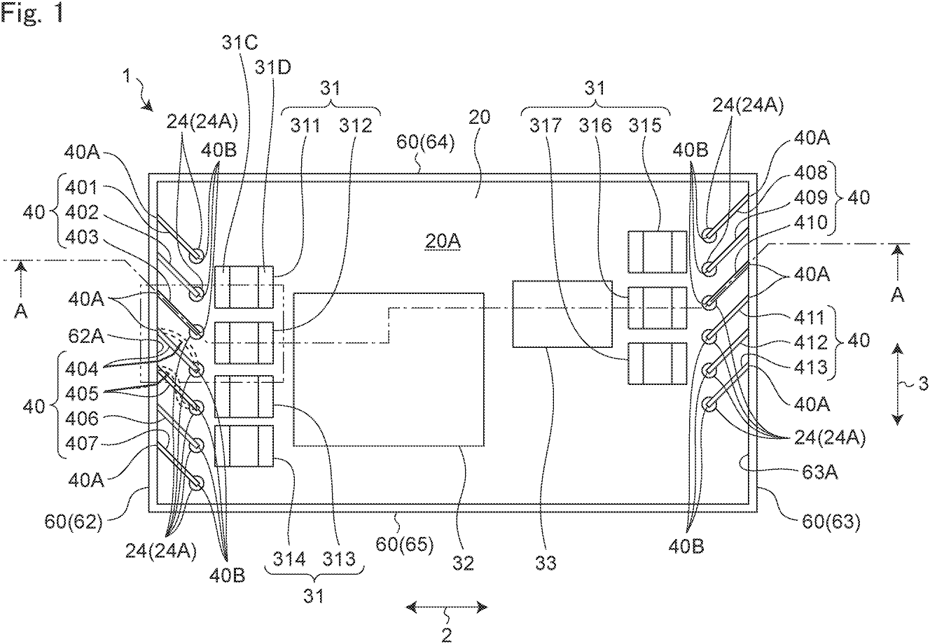

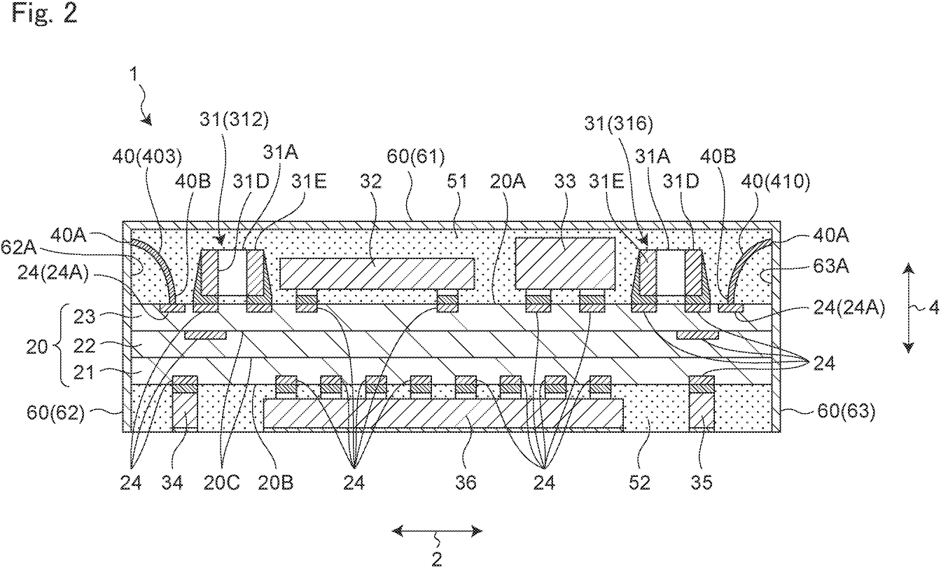

FIG. 1 is a plan view of a circuit module according to a first embodiment of the present disclosure. FIG. 2 is a cross-sectional view taken along the line A-A in FIG. 1.

In a circuit module 1 illustrated in FIGS. 1 and 2, various electronic components are mounted on a front surface and a back surface of a substrate, and an insulating resin layer is formed on the front surface and the back surface of the substrate so as to wrap the electronic components. The circuit module 1 is used for, for example, wireless devices such as mobile phones and automobile phones, and other various communication devices.

As illustrated in FIGS. 1 and 2, the circuit module 1 includes a substrate 20, electronic components 31 to 36, sealing resins 51 and 52, a shield film 60, and wires 40. Note that, in FIG. 1 and FIGS. 5 to 8 to be described later, illustration of an upper film 61 of the shield film 60 and the sealing resins 51 and 52 is omitted.

The circuit module 1 has a rectangular parallelepiped shape as a whole. In the following description, directions of respective sides of the circuit module 1 having a rectangular parallelepiped shape are defined as a longitudinal direction 2, a lateral direction 3, and a height direction 4, respectively. A side of the shield film 60 on which the upper film 61 (see FIG. 2) is located is defined as an upper side in the height direction 4. Note that the shape of the circuit module 1 is not limited to a rectangular parallelepiped shape.

The substrate 20 is made of resin such as glass epoxy, Teflon (registered trademark), and paper phenol, ceramic such as alumina, or the like. As illustrated in FIG. 1, the substrate 20 is spread in the longitudinal direction 2 and the lateral direction 3.

In the first embodiment, as illustrated in FIG. 2, the substrate 20 is a three-layer substrate in which three substrates 21, 22, and 23 are stacked in order from a bottom. The substrate 20 is stacked in the height direction 4. Note that the substrate 20 may be a multilayer substrate having a number of layers other than three, or may be a single-layer substrate.

A plurality of via conductors (not illustrated) are formed in the substrate 20. In the case of a resin substrate, each of the via conductors is formed by plating a conductive metal made of copper or the like in a through hole (via) vertically penetrating the substrates 21, 22, and 23, or in the case of a ceramic substrate, the via conductor is filled with a conductive paste and co-fired with a ceramic.

A plurality of wiring electrodes 24 are formed on the substrate 20. The wiring electrodes 24 are formed on a front surface 20A of the substrate 20 (an upper surface of the substrate 23), a back surface 20B of the substrate 20 (a lower surface of the substrate 21), and an inner surface 20C sandwiched between two adjacent substrates of the substrates 21, 22, and 23. The front surface 20A and the back surface 20B are surfaces orthogonal to the height direction 4. Note that, in the first embodiment, the wiring electrodes 24 are not formed on the inner surface 20C between the substrates 21 and 22 among the two inner surfaces 20C, but may be formed.

In the case of a ceramic substrate, the wiring electrode 24 is obtained by printing a conductive paste on pads formed on each surface (front surface 20A, back surface 20B, inner surface 20C) of the substrate 20 and co-firing the paste with the ceramic substrate. The conductive paste is made of, for example, copper. In the case of a resin substrate, the wiring electrode 24 is formed on a pad on each surface of the substrate 20 by a known means such as etching a metal foil. Each wiring electrode 24 is electrically connected to another wiring electrode 24 via the via conductor. At least a part of the wiring electrode 24 formed on the back surface 20B of the substrate 20 is a terminal electrode. In a case where the circuit module 1 is mounted on a substrate or the like (not illustrated), the terminal electrode is connected to a wiring electrode formed on the substrate or the like.

As illustrated in FIGS. 1 and 2, 12 electronic components are mounted on the substrate 20. In the first embodiment, the 12 electronic components are seven inductors 31, one low noise amplifier (LNA) 32, one antenna switch 33, two capacitors 34 and 35, and one integrated circuit 36. The inductors 31, the LNA 32, and the antenna switch 33 are mounted on the front surface 20A of the substrate 20. The capacitors 34 and 35 and the integrated circuit 36 are mounted on the back surface 20B of the substrate 20.

Note that the arrangement positions of the electronic components mounted on the substrate 20 are not limited to the arrangement positions illustrated in FIG. 1. The number of electronic components mounted on the substrate 20 is not limited to 12. The number of each of the inductors 31, the LNA 32, the antenna switch 33, the capacitors 34 and 35, and the integrated circuit 36 mounted on the substrate 20 is not limited to the number described above. Types of electronic components are not limited to those described above (inductors 31, LNA 32, antenna switch 33, capacitors 34 and 35, and integrated circuit 36), and various electronic components such as resistors can be mounted on the substrate 20.

In the first embodiment, each electronic component is of a surface mounting type and is mounted on the substrate 20 by soldering. Note that each electronic component can be mounted on the substrate 20 by various known mounting methods, for example, by a flip-chip method or a wire bonding method. Furthermore, each electronic component may be an insertion type instead of the surface mounting type.

In the first embodiment, among the seven inductors 31 (inductors 311 to 317), the inductors 311 to 314 are elements constituting a matching circuit of the LNA 32. The inductors 311 to 314 are electrically connected to the LNA 32 directly or indirectly via another electronic component.

In the first embodiment, among the seven inductors 31 (inductors 311 to 317), the inductors 315 to 317 are elements constituting a matching circuit of the antenna switch 33. The inductors 315 to 317 are electrically connected to the antenna switch 33 directly or indirectly via another electronic component.

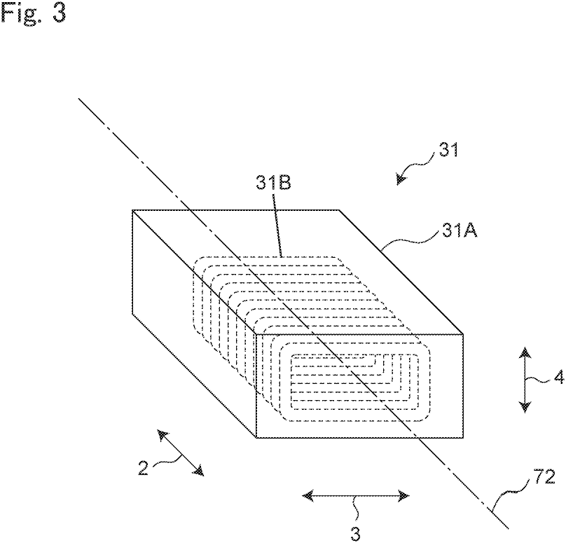

FIG. 3 is a perspective view of the inductor 31. As illustrated in FIG. 3, the inductor 31 includes a casing 31A and a coil unit 31B.

The casing 31A covers the coil unit 31B. As illustrated in FIGS. 1 and 2, two external terminals 31C and 31D are formed in the casing 31A. Each of the external terminals 31C and 31D is electrically connected to the wiring electrode 24.

As illustrated in FIG. 3, the coil unit 31B is configured by winding a conductive wire around a winding axis 72 along the longitudinal direction 2. One end portion of the coil unit 31B is electrically connected to the external terminal 31C. The other end portion of the coil unit 31B is electrically connected to the external terminal 31D. The arrangement positions and shapes of the external terminal 31C and the external terminal 31D in the inductor 31 are not limited to those illustrated in FIG. 1. The winding axis 72 may be along a direction other than the longitudinal direction 2, for example, may be along the lateral direction 3.

As illustrated in FIG. 2, the sealing resin 51 is provided on the front surface 20A of the substrate 20. The sealing resin 52 is provided on the back surface 20B of the substrate 20. The sealing resins 51 and 52 are made of an electrically insulated resin such as an epoxy resin.

The sealing resin 51 covers the inductors 31, the LNA 32, and the antenna switch 33. The sealing resin 52 covers the capacitors 34 and 35 and the integrated circuit 36. In the first embodiment, each of the electronic components 31 to 36 is completely embedded in the sealing resins 51 and 52.

Note that the sealing resins 51 and 52 may cover only a part of each of the electronic components 31 to 36. For example, while an electronic component small in the height direction 4 may be completely embedded with any one of the sealing resins 51 and 52, a portion of the electronic component large in the height direction 4 excluding an upper surface thereof may be embedded with any one of the sealing resins 51 and 52.

As illustrated in FIG. 2, the shield film 60 is provided so as to cover the substrate 20 and the sealing resins 51 and 52 from above. The shield film 60 is made of a conductive member such as copper. The shield film 60 may have a configuration in which a plurality of conductive members are stacked.

As illustrated in FIGS. 1 and 2, the shield film 60 includes an upper film 61 and side films 62 to 65.

The side films 62 to 65 extend downward from a peripheral edge of the upper film 61. The side film 62 extends downward from one end portion in the longitudinal direction 2 of the upper film 61. The side film 63 extends downward from the other end portion in the longitudinal direction 2 of the upper film 61. The side film 64 extends downward from one end portion in the lateral direction 3 of the upper film 61. The side film 65 extends downward from the other end portion in the lateral direction 3 of the upper film 61. End portions of the side films 62 and 63 in the lateral direction 3 and end portions of the side films 64 and 65 in the longitudinal direction 2 are connected to each other. As described above, the shield film 60 has a box shape opened downward.

Note that the side films 62 to 65 may not extend directly downward from the upper film 61. For example, the side films 62 to 65 may extend from the upper film 61 along a direction inclined with respect to the height direction 4. Here, the front surface 20A of the substrate 20 is a surface orthogonal to the height direction 4. That is, the side films 62 to 65 may extend in a direction intersecting the front surface 20A of the substrate 20.

As illustrated in FIG. 2, the upper film 61 is in contact with an upper surface of the sealing resin 51. That is, the upper film 61 covers an upper side of the sealing resin 51.

The side films 62 to 65 are in contact with side surfaces of the sealing resins 51 and 52 and a side surface of the substrate 20. That is, the side films 62 to 65 cover the sides of the sealing resins 51 and 52 and the sides of the substrate 20.

As illustrated in FIG. 2, the upper film 61 covers the plurality of electronic components (inductors 31, LNA 32, and antenna switch 33) mounted on the substrate 20.

As illustrated in FIG. 1, an upper portion of each of the side films 62 to 65 surrounds the plurality of electronic components (inductors 31, LNA 32, and antenna switch 33) mounted on the substrate 20 in plan view when the front surface 20A of the substrate 20 is viewed along the height direction 4.

Although not illustrated, a lower portion of each of the side films 62 to 65 surrounds the plurality of electronic components (capacitors 34 and 35, and integrated circuit 36) mounted on the substrate 20 in a bottom view when the back surface 20B of the substrate 20 is viewed along the height direction 4.

The shield film 60 is grounded by being directly or indirectly connected to a casing or the like of a device to which the circuit module 1 is attached. That is, a potential of the shield film 60 is the ground potential.

Note that the shield film 60 may cover at least a part of the sealing resin 50. For example, the shield film 60 may not include the upper film 61. In this case, the shield film 60 covers a side of the sealing resin 50 but does not cover an upper side of the sealing resin 50.

As illustrated in FIGS. 1 and 2, a plurality of the wires 40 is disposed on the front surface 20A of the substrate 20. In the first embodiment, the circuit module 1 includes 13 wires 40 (wires 401 to 413). The number of wires 40 is not limited to 13. The number of wires 40 may be one or more.

Each of the wires 40 has conductivity, and is made of, for example, gold, copper, or the like. The wire 40 is an example of the conductive member.

As illustrated in FIG. 1, in plan view, the wires 401 to 407 are arranged between the inductors 311 to 314 and the side film 62 of the shield film 60. In plan view, the wires 401 to 407 are arranged at positions sandwiching the inductors 311 to 314 with the LNA 32. In other words, in plan view, the LNA 32 is located on an opposite side of the wires 401 to 407 with respect to the inductors 311 to 314.

In plan view, the wires 401 to 407 are arranged side by side along the lateral direction 3. In plan view, the wires 401 to 407 are arranged at equal intervals. The wires 401 to 407 are arranged parallel to each other in plan view. Note that the wires 401 to 407 may not be arranged at equal intervals. Furthermore, the wires 401 to 407 do not need to be completely parallel to each other, and may be substantially parallel. Furthermore, the wires 401 to 407 may not be parallel to each other.

In plan view, the wires 408 to 413 are arranged between the inductors 315 to 317 and the side film 63 of the shield film 60. In plan view, the wires 408 to 413 are arranged at positions sandwiching the inductors 315 to 317 with the antenna switch 33. In other words, in plan view, the antenna switch 33 is located on an opposite side of the wires 408 to 413 with respect to the inductors 315 to 317.

In plan view, the wires 408 to 413 are arranged side by side along the lateral direction 3. In plan view, the wires 408 to 413 are arranged at equal intervals. The wires 408 to 413 are arranged parallel to each other in plan view. Note that the wires 408 to 413 may not be arranged at equal intervals. Furthermore, the wires 408 to 413 do not need to be completely parallel to each other, and may be substantially parallel. Furthermore, the wires 408 to 413 may not be parallel to each other.

The wires 401 to 413 are electrically connected to the shield film 60 and the wiring electrodes 24A. The wiring electrode 24A is a part of the plurality of wiring electrodes 24. The wiring electrode 24A is formed on the front surface 20A of the substrate 20. The wiring electrode 24A is an example of the wiring portion. The shield film 60 and the wiring electrode 24A are electrically connected to each other via the wires 401 to 413. That is, in the first embodiment, the wiring electrode 24A is grounded via the wires 401 to 413 and the shield film 60.

Note that the wiring electrode 24A may be grounded instead of the shield film 60 being grounded. In this case, the shield film 60 is grounded via the wires 401 to 413 and the wiring electrode 24A. Furthermore, both the wiring electrode 24A and the shield film 60 may be grounded.

One end portion 40A of each of the wires 401 to 407 is connected to a facing surface 62A of the side film 62 of the shield film 60. The facing surface 62A of the side film 62 is a surface facing the inside of the circuit module 1 among the surfaces of the side film 62. The facing surface 62A faces the inductors 311 to 314 in the longitudinal direction 2.

One end portion 40A of each of the wires 408 to 413 is connected to a facing surface 63A of the side film 63 of the shield film 60. The facing surface 63A of the side film 63 is a surface facing the inside of the circuit module 1 among the surfaces of the side film 63. The facing surface 63A faces the inductors 315 to 317 in the longitudinal direction 2.

The facing surfaces 62A and 63A are spread in the lateral direction 3 and the height direction 4. In other words, the facing surfaces 62A and 63A extend in the lateral direction 3 and the height direction 4.

The one end portion 40A of each of the wires 401 to 413 is connected to the shield film 60 by a known means such that after wire bonding and resin application, the resin is cut so as to expose a cross section of the wire, and the shield film is attached to a cut surface of the resin. The one end portion 40A of each of the wires 401 to 413 is an example of the first portion.

The other end portion 40B of each of the wires 401 to 413 is connected to the front surface 20A of the substrate 20. Specifically, the other end portion 40B of each of the wires 401 to 413 is connected to the wiring electrode 24A formed on the front surface 20A of the substrate 20. The other end portion 40B of each of the wires 401 to 413 is connected to the wiring electrode 24A by a known means such as wire bonding. The other end portion 40B of each of the wires 401 to 413 is an example of the second portion.

Note that a portion other than the one end portion 40A of each of the wires 401 to 413 may be connected to the shield film 60, and a portion other than the other end portion 40B of each of the wires 401 to 413 may be connected to the wiring electrode 24A.

In the first embodiment, the wiring electrode 24A is formed corresponding to each of the wires 401 to 413. These wiring electrodes 24A may be electrically connected to each other on at least one of the front surface 20A, the back surface 20B, and the inner surface 20C of the substrate 20, or may not be electrically connected to each other.

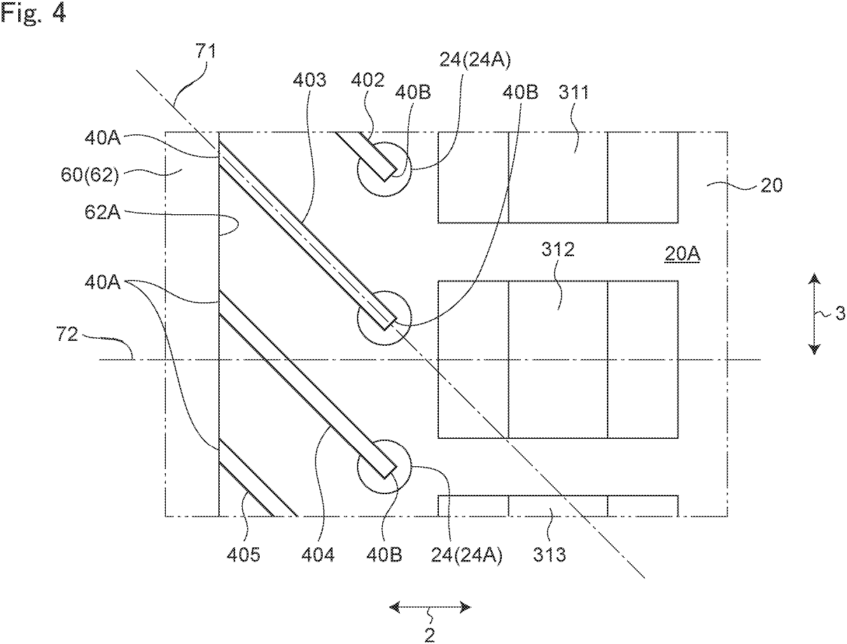

FIG. 4 is an enlarged view of a portion indicated by a two-dot chain line in FIG. 1. As illustrated in FIG. 4, in plan view, an imaginary straight line 71 passing through the one end portion 40A and the other end portion 40B of the wire 403 is inclined with respect to the facing surface 62A of the side film 62 of the shield film 60. In other words, the imaginary straight line 71 extends in such a way that a position in the lateral direction 3 changes as it goes away from the facing surface 62A along the longitudinal direction 2. Note that an imaginary straight line passing through the one end portion 40A and the other end portion 40B of each of the wires 401, 402, 404 to 407 is also inclined with respect to the facing surface 62A of the side film 62 of the shield film 60.

Similarly, an imaginary straight line passing through the one end portion 40A and the other end portion 40B of each of the wires 408 to 413 is inclined with respect to the facing surface 63A of the side film 63 of the shield film 60. In other words, the imaginary straight line extends in such a way that the position in the lateral direction 3 changes as the imaginary straight line separates from the facing surface 63A along the longitudinal direction 2.

In the first embodiment, in plan view, each imaginary straight line corresponding to each of the wires 401 to 413 coincides with a direction in which each of the corresponding wires 401 to 413 extends. However, in plan view, each imaginary straight line may not coincide with the direction in which each of the corresponding wires 401 to 413 extends. For example, the wires 404 and 405 may be curved in plan view as indicated by a broken line in FIG. 1. Even in this case, each imaginary straight line passing through the one end portion 40A and the other end portion 40B of each of the wires 404 and 405 is inclined with respect to the facing surface 62A of the side film 62 of the shield film 60.

The imaginary straight line 71 passing through the one end portion 40A and the other end portion 40B of the wire 403 is inclined with respect to the winding axis 72 of the inductor 312. Note that a relationship in which the imaginary straight line 71 is inclined with respect to the winding axis 72 is also established between each of the wires 401 to 407 and each of the inductors 311 to 314, and is also established between each of the wires 408 to 413 and each of the inductors 315 to 317.

In the first embodiment, the imaginary straight line 71 and the winding axis 72 of the inductor 31 intersect with each other, but are not orthogonal to each other in plan view. Furthermore, in plan view, the imaginary straight line 71 and the winding axis 72 of the inductor 31 are not parallel to each other.

In the lateral direction 3 along the facing surfaces 62A and 63A of the shield film 60 and parallel to the front surface 20A of the substrate 20, the other end portion 40B of the wire 403, which is one of the two adjacent wires 403 and 404, is located between the one end portion 40A and the other end portion 40B of the wire 404, which is the other of the two adjacent wires 403 and 404. Note that the above-described positional relationship (the relationship in which the other end portion 40B of one of the two adjacent wires 40 is located between the one end portion 40A and the other end portion 40B of the other of the two wires 40) also holds between the two adjacent wires 40 other than the wires 403 and 404.

According to the first embodiment, the pseudo inductor is formed by the wire 40, the side films 62 and 63 of the shield film 60, and the wiring electrodes 24A. Furthermore, according to the first embodiment, the imaginary straight line 71 passing through the one end portion 40A and the other end portion 40B of the wire 40 is inclined with respect to the facing surfaces 62A and 63A of the side films 62 and 63 in plan view. That is, the pseudo inductor is inclined with respect to the facing surfaces 62A and 63A. Therefore, the lines of magnetic force generated by a magnetic field due to noise transmitted through the shield film 60 extend perpendicularly from the facing surfaces 62A and 63A toward the inductor 31 mounted on the substrate 20, but are redirected in the pseudo inductor. Accordingly, the redirected lines of magnetic force travel so as to avoid the inductor 31 mounted on the substrate 20. As a result, coupling between the lines of magnetic force extending from the shield film 60 and the lines of magnetic force generated in the inductor 31 mounted on the substrate 20 is reduced.

According to the first embodiment, the direction in which the lines of magnetic force passing through the pseudo inductor formed by the wire 40, the side films 62 and 63 of the shield film 60, and the wiring electrodes 24A travel is a direction inclined with respect to the lines of magnetic force due to the magnetic field generated in the inductor 31 mounted on the substrate 20. Therefore, only a part of the vector component decomposed components in the lines of magnetic force passing through the pseudo inductor is coupled with the lines of magnetic force generated in the inductor 31 among the lines of magnetic force passing through the pseudo inductor. Specifically, a component in the longitudinal direction 2 of the lines of magnetic force having passed through the pseudo inductor is coupled to the lines of magnetic force generated in the inductor 31. On the other hand, a component in the lateral direction 3 of the lines of magnetic force having passed through the pseudo inductor is not coupled with the lines of magnetic force generated in the inductor 31. Therefore, coupling between the lines of magnetic force extending from the shield film 60 and the lines of magnetic force generated in the inductor 31 is reduced.

According to the first embodiment, the LNA 32 and the antenna switch 33 are electrically connected to the inductor 31. Therefore, when the inductor 31 is affected by noise transmitted through the shield film 60, characteristics of the LNA 32 and the antenna switch 33 may be deteriorated. However, according to the first embodiment, coupling between the lines of magnetic force extending from the shield film 60 and the lines of magnetic force generated in the inductor 31 is reduced. Therefore, deterioration of the characteristics of the LNA 32 and the antenna switch 33 can be suppressed.

According to the first embodiment, the conductive member is the wire 40. The wire 40 is easily curved and bent, and is also easily electrically connected to the shield film 60 and the wiring electrodes 24A. Therefore, the pseudo inductor can be easily formed by the conductive member, the side films 62 and 63 of the shield film 60, and the wiring electrodes 24A.

According to the first embodiment, the circuit module 1 includes a plurality of the wires 40. Therefore, the lines of magnetic force extending from the side films 62 and 63 of the shield film 60 can be redirected over a wide range.

According to the first embodiment, the plurality of the wires 40 are arranged in parallel or substantially parallel to each other in plan view. As a result, the lines of magnetic force of each of the wires 40 are redirected in the same direction or substantially the same direction. Therefore, for example, it is easy to cope with not arranging the inductor 31 ahead in the traveling direction of the redirected lines of magnetic force.

According to the first embodiment, the plurality of the wires 40 are arranged in parallel or substantially parallel to each other in plan view. As a result, the plurality of wires 40 can be arranged in higher density than in a case where the plurality of wires 40 are not arranged in parallel or substantially parallel to each other.

According to the first embodiment, the other end portion 40B of one of the two adjacent wires 40 is located between the one end portion 40A and the other end portion 40B of the other of the two wires 40. Therefore, when viewed in the longitudinal direction 2 from the facing surfaces 62A and 63A of the side films 62 and 63, the boundary portions of the two adjacent wires 40 overlap with each other. Therefore, it is possible to increase the possibility that the lines of magnetic force traveling from the facing surfaces 62A and 63A of the side films 62 and 63 to the boundary portions are redirected by any of the two wires 40.

In the first embodiment, the LNA 32 and the antenna switch 33 are mounted on the front surface 20A of the substrate 20, but may be mounted on the back surface 20B of the substrate 20.

In the first embodiment, the LNA 32 is located on an opposite side of the wires 401 to 407 with respect to the inductors 311 to 314, but may not be located on the opposite side. For example, the LNA 32 may be arranged side by side with the inductors 311 to 314 along the lateral direction 3. Furthermore, in the first embodiment, the antenna switch 33 is located on an opposite side of the wires 408 to 413 with respect to the inductors 315 to 317, but may not be located on the opposite side.

In the first embodiment, the wires 401 to 407 are arranged side by side along the lateral direction 3 in plan view, but may be arranged side by side along the longitudinal direction 2. Furthermore, the wires 401 to 407 may not be arranged side by side in plan view. Similarly, in plan view, the wires 408 to 413 may be arranged side by side along the longitudinal direction 2 or may not be arranged side by side.

In the first embodiment, the other end portion 40B of one of the two adjacent wires 40 is located between the one end portion 40A and the other end portion 40B of the other of the two adjacent wires 40, but may not be located therebetween. For example, the other end portion 40B of one of the two adjacent wires 40 may be located closer to a side of the one end portion 40A of one of the two adjacent wires 40 than the one end portion 40A of the other of the two adjacent wires 40. In other words, the other end portion 40B of one of the two adjacent wires 40 may be located between the one end portion 40A of one of the two adjacent wires 40 and the one end portion 40A of the other of the two adjacent wires 40.

### Second Embodiment

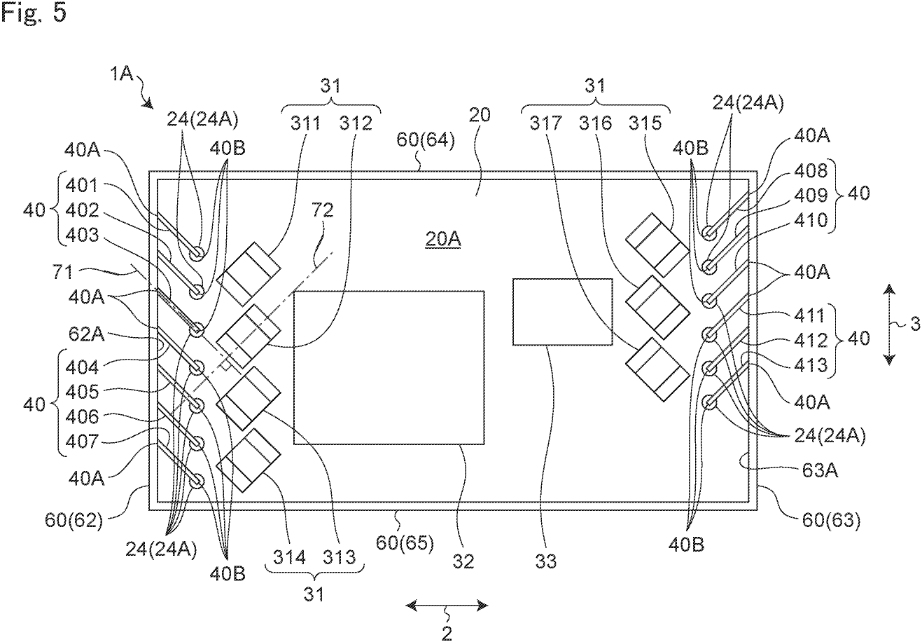

FIG. 5 is a plan view of a circuit module according to a second embodiment of the present disclosure. A circuit module 1A according to the second embodiment is different from the circuit module 1 according to the first embodiment in that an imaginary straight line 71 is orthogonal to a winding axis 72 of an inductor in the circuit module 1A according to the second embodiment.

As illustrated in FIG. 5, inductors 311 to 314 are arranged to be inclined with respect to a facing surface 62A of a side film 62 of a shield film 60. Inductors 315 to 317 are arranged to be inclined with respect to a facing surface 63A of a side film 63 of the shield film 60. Accordingly, in the second embodiment, the winding axis 72 of each of the inductors 311 to 314 extends in a direction inclined with respect to the facing surface 62A, and the winding axis 72 of each of the inductors 315 to 317 extends in a direction inclined with respect to the facing surface 63A.

The imaginary straight line 71 passing through one end portion 40A and the other end portion 40B of the wire 403 is orthogonal to the winding axis 72 of the inductor 312. Note that the relationship in which the imaginary straight line 71 is orthogonal to the winding axis 72 is established between each of the wires 401 to 407 and each of the inductors 311 to 314, and is established between each of the wires 408 to 413 and each of the inductors 315 to 317.

### Third Embodiment

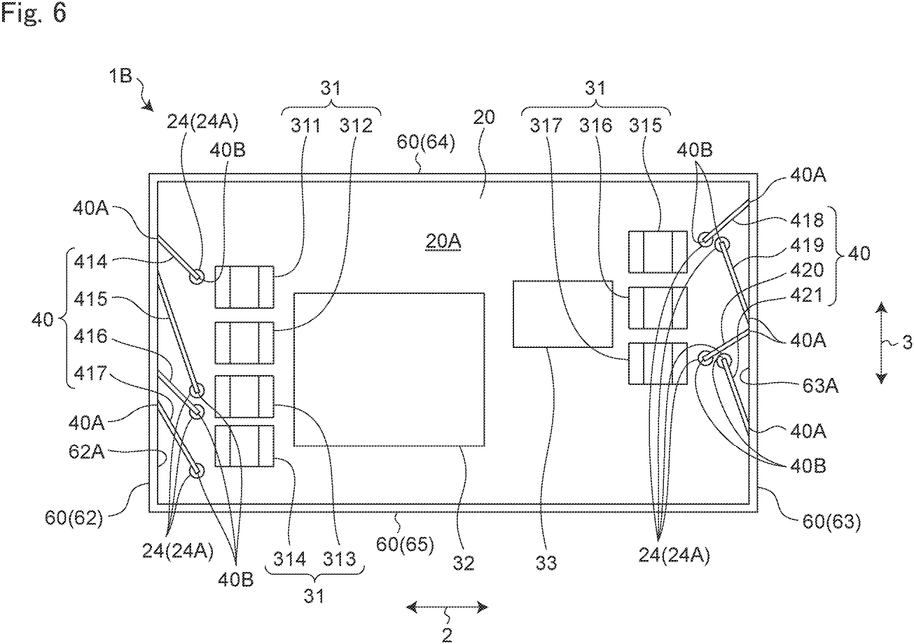

FIG. 6 is a plan view of a circuit module according to a third embodiment of the present disclosure. The circuit module 1B according to the third embodiment is different from the circuit module 1 according to the first embodiment in that wires 40 are not parallel to each other in the circuit module 1B according to the third embodiment.

As illustrated in FIG. 6, a circuit module 1B includes eight wires 40 (wires 414 to 421). Specifically, the circuit module 1B includes wires 414 to 417 instead of the wires 401 to 407, and includes wires 418 to 421 instead of the wires 408 to 413.

The wires 414 to 417 are arranged side by side along the lateral direction 3, but are not parallel to each other. The wires 414 to 417 are inclined with respect to a facing surface 62A of a side film 62 of a shield film 60, but angles of the inclinations are different from each other. That is, an imaginary straight line passing through one end portion 40A and the other end portion 40B of each of the wires 414 to 417 is inclined with respect to the facing surface 62A, but the angles of the inclinations are different from each other.

The wires 418 to 421 are arranged side by side along the lateral direction 3, but are not parallel to each other. The wires 418 to 421 are inclined with respect to a facing surface 63A of a side film 63 of the shield film 60. However, an inclination direction of the wires 418 and 420 is different from an inclination direction of the wires 419 and 421.

Note that the wires 414 to 417 are configured similarly to the wires 401 to 407 of the circuit module 1 according to the first embodiment except for the above-described difference. Furthermore, the wires 418 to 421 are configured similarly to the wires 408 to 413 of the circuit module 1 according to the first embodiment except for the above-described difference.

### Fourth Embodiment

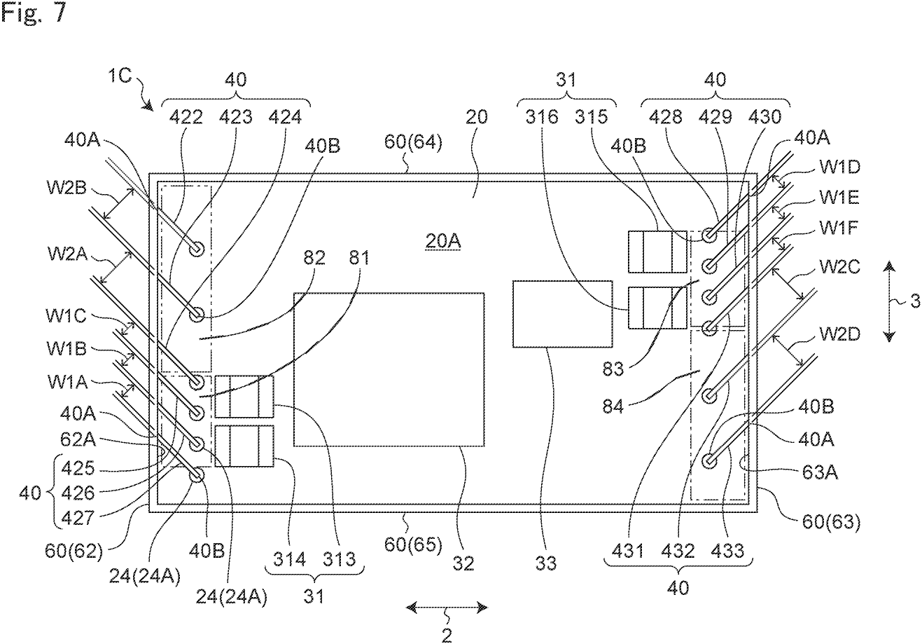

FIG. 7 is a plan view of a circuit module according to a fourth embodiment of the present disclosure. A circuit module 1C according to the fourth embodiment is different from the circuit module 1 according to the first embodiment in that, in the circuit module 1C according to the third embodiment, wires 40 are arranged not only in a region between inductors 31 and each of side films 62 and 63 on a front surface 20A of a substrate 20 but also in a region other than the region between the inductors 31 and each of the side films 62 and 63 in plan view.

As illustrated in FIG. 7, the circuit module 1C includes 12 wires 40 (wires 422 to 433). Specifically, the circuit module 1C includes wires 422 to 427 instead of the wires 401 to 407, and includes wires 428 to 433 instead of the wires 408 to 413.

Furthermore, the circuit module 1C includes four inductors 31. Specifically, the circuit module 1C includes only inductors 313 to 316 among the inductors 311 to 317 included in the circuit module 1 according to the first embodiment.

The wires 425 to 427 are arranged in a facing region 81. The wires 422 to 424 is arranged in a non-facing region 82. The facing region 81 is between the inductors 313 and 314 and the side film 62 of the shield film 60 on the front surface 20A of the substrate 20. The facing region 81 is surrounded by an alternate long and short dash line in FIG. 7. The non-facing region 82 is deviated in the lateral direction 3 from between the inductors 313 and 314 and the side film 62 of the shield film 60 (facing region 81) on the front surface 20A of the substrate 20. The non-facing region 82 is surrounded by a two-dot chain line in FIG. 7. That is, the non-facing region 82 is not between the inductors 313 and 314 and the side film 62 of the shield film 60 on the front surface 20A of the substrate 20.

The wires 428 to 431 are arranged in a facing region 83. The wires 432 and 433 are arranged in a non-facing region 84. The facing region 83 is between the inductors 315 and 316 and the side film 63 of the shield film 60 on the front surface 20A of the substrate 20. The facing region 83 is surrounded by an alternate long and short dash line in FIG. 7. The non-facing region 84 is deviated in the lateral direction 3 from between the inductors 315 and 316 and the side film 63 of the shield film 60 (facing region 83) on the front surface 20A of the substrate 20. The non-facing region 84 is surrounded by a two-dot chain line in FIG. 7. That is, the non-facing region 84 is not between the inductors 315 and 316 and the side film 62 of the shield film 60 on the front surface 20A of the substrate 20.

Each of intervals W1A, W1B, and W1C between the two adjacent wires 40 in the facing region 81 is shorter than each of intervals W2A and W2B between the two adjacent wires 40 in the non-facing region 82. The interval W1A is a length between the wires 426 and 427. The interval W1B is a length between the wires 425 and 426. The interval W1C is a length between the wires 424 and 425. The interval W2A is a length between the wires 423 and 424. The interval W2B is a length between the wires 422 and 423. Note that in the fourth embodiment, the intervals W1A, W1B, and W1C are equal to each other, but may be different from each other. Furthermore, in the fourth embodiment, the intervals W2A and W2B are equal to each other, but may be different from each other.

Each of intervals W1D, W1E, and W1F between the two adjacent wires 40 in the facing region 83 is shorter than each of intervals W2C and W2D between the two adjacent wires 40 in the non-facing region 84. The interval W1D is a length between the wires 428 and 429. The interval W1E is a length between the wires 429 and 430. The interval W1F is a length between the wires 430 and 431. The interval W2C is a length between the wires 431 and 432. The interval W2D is a length between the wires 432 and 433. Note that in the fourth embodiment, the intervals W1D, W1E, and W1F are equal to each other, but may be different from each other. Furthermore, in the fourth embodiment, the intervals W2C and W2D are equal to each other, but may be different from each other.

The lines of magnetic force from the facing surfaces 62A and 63A of the side films 62 and 63 toward the inductors 313 to 316 through the non-facing regions 82 and 84 are smaller than the lines of magnetic force from the facing surfaces 62A and 63A of the side films 62 and 63 toward the inductors 313 to 316 through the facing regions 81 and 83. According to the fourth embodiment, it is possible to arrange a large number of wires 40 in the facing regions 81 and 83 where there are many lines of magnetic force toward the inductors 313 to 316. On the other hand, a space occupied by the wires 40 on the front surface 20A of the substrate 20 can be reduced by reducing the number of wires 40 arranged in the non-facing regions 82 and 84 where the lines of magnetic force toward the inductors 313 to 316 are small. As a result, it is possible to increase a space where other members are arranged on the front surface 20A of the substrate 20.

### Fifth Embodiment

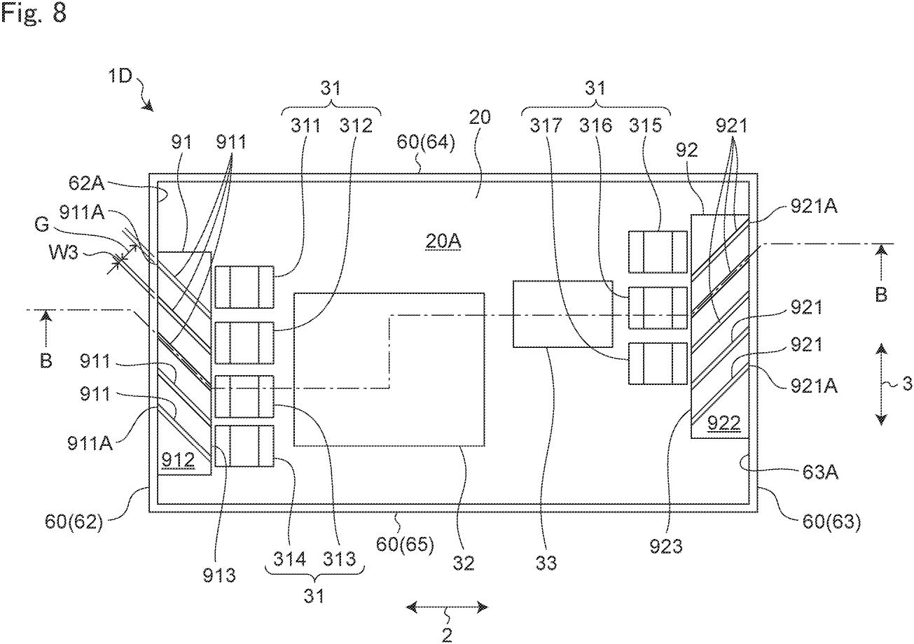

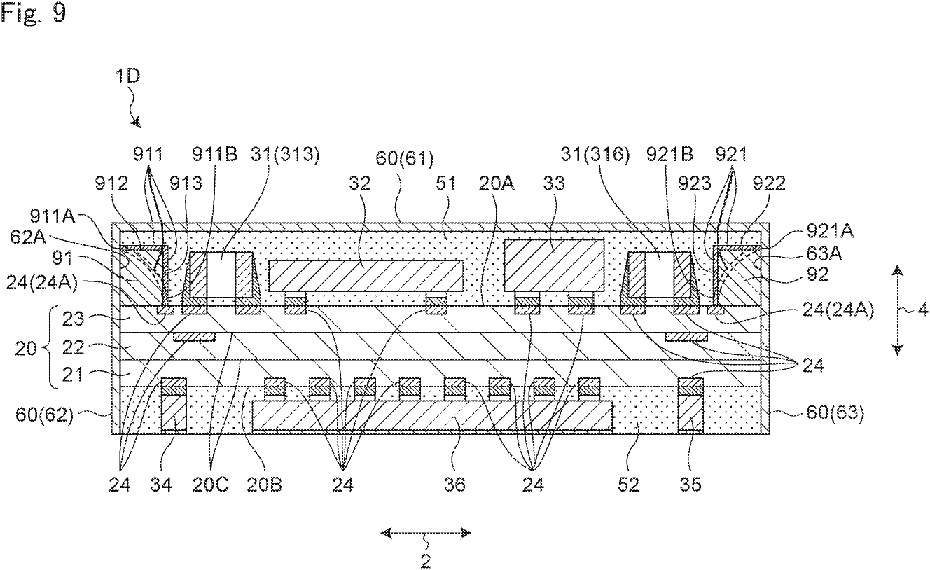

FIG. 8 is a plan view of a circuit module according to a fifth embodiment of the present disclosure. FIG. 9 is a cross-sectional view taken along the line B-B in FIG. 8. A circuit module 1D according to the fifth embodiment is different from the circuit module 1 according to the first embodiment in that the conductive member is not the wire 40. That is, the conductive member is not limited to the wire.

As illustrated in FIGS. 8 and 9, the circuit module 1D according to the fifth embodiment includes a joining member 91 instead of the wires 401 to 407 (see FIG. 1), and includes a joining member 92 instead of the wires 408 to 413. The joining member 91 is disposed in a region where the wires 401 to 407 are arranged in the first embodiment. The joining member 92 is disposed in a region where the wires 408 to 413 are arranged in the first embodiment. In the fifth embodiment, the joining members 91 and 92 have a rectangular parallelepiped shape. The joining members 91 and 92 are examples of the conductive member.

The joining member 91 is in contact with a facing surface 62A of a side film 62 of a shield film 60. A plurality of wiring patterns 911 are formed on an upper surface 912 and a side surface 913 of the joining member 91. The side surface 913 faces inductors 311 to 314. Each of the wiring patterns 911 is made of a conductor such as copper. Note that a portion of the joining member 91 other than the wiring patterns 911 is made of an electrically insulated resin such as an epoxy resin.

In plan view, the plurality of wiring patterns 911 are formed side by side along the lateral direction 3. In plan view, the plurality of wiring patterns 911 are formed at equal intervals and in parallel. Note that the plurality of wiring patterns 911 may not be formed at equal intervals. Furthermore, the plurality of wiring patterns 911 may not be parallel to each other.

The joining member 92 is in contact with a facing surface 63A of the side film 62 of the shield film 60. A plurality of wiring patterns 921 are formed on an upper surface 922 and a side surface 923 of the joining member 92. The side surface 923 faces inductors 315 to 317. Each of the wiring patterns 921 is made of a conductor such as copper. Note that a portion of the joining member 92 other than the wiring patterns 921 is made of an electrically insulated resin such as an epoxy resin.

In plan view, the plurality of wiring patterns 921 are formed side by side along the lateral direction 3. In plan view, the plurality of wiring patterns 921 are formed at equal intervals and in parallel. Note that the plurality of wiring patterns 921 may not be formed at equal intervals. Furthermore, the plurality of wiring patterns 921 may not be parallel to each other.

The wiring patterns 911 and 921 are electrically connected to the shield film 60 and wiring electrodes 24A by a known means. The known means is, for example, a means for forming a pattern on a rectangular parallelepiped resin by photolithography or the like, connecting the formed pattern and a wiring electrode to each other using solder, and for the formed pattern and a shield film, cutting the resin such that a cross section of the pattern is exposed, and attaching the shield film to a cut surface of the resin.

One end portion 911A of each of the wiring patterns 911 is connected to the facing surface 62A of the side film 62 of the shield film 60. One end portion 921A of each of the wiring patterns 921 is connected to the facing surface 63A of the side film 63 of the shield film 60 by the known means as described above. The one end portions 911A and 921A are examples of the first portion.

As illustrated in FIG. 9, the other end portion 911B of each of the wiring patterns 911 and the other end portion 921B of each of the wiring patterns 921 are connected to the wiring electrodes 24A formed on the front surface 20A of the substrate 20 by the known means as described above. The other end portions 911B and 921B are examples of the second portion.

Note that a portion other than the one end portion 911A of each of the wiring patterns 911 and a portion other than the one end portion 921A of each of the wiring patterns 921 may be connected to the shield film 60. Furthermore, a portion other than the other end portion 911B of each of the wiring patterns 911 and a portion other than the other end portion 921B of each of the wiring patterns 921 may be connected to the wiring electrodes 24A.

As illustrated in FIG. 8, in plan view, each of the wiring patterns 911 is inclined with respect to the facing surface 62A of the side film 62 of the shield film 60, and each of the wiring patterns 921 is inclined with respect to the facing surface 63A of the side film 63 of the shield film 60. That is, in the fifth embodiment, as in the first embodiment, an imaginary straight line passing through the one end portion 911A and the other end portion 911B of each of the wiring patterns 911 is inclined with respect to the facing surface 62A, and an imaginary straight line passing through the one end portion 921A and the other end portion 921B of each of the wiring patterns 921 is inclined with respect to the facing surface 63A.

In the fifth embodiment, the joining members 91 and 92 are not limited to a rectangular parallelepiped shape. For example, as indicated by broken lines in FIG. 9, upper surfaces and side surfaces of the joining members 91 and 92 may be formed of curved surfaces. In this case, the wiring patterns 911 and 921 also extend along the curved surfaces.

Note that, by appropriately combining arbitrary embodiments among the various embodiments described above, the effects of the respective embodiments can be achieved.

Although the present disclosure has been fully described in connection with the preferred embodiments thereof with reference to the drawings as appropriate, it is to be noted that various changes and modifications are apparent to those skilled in the art. Such changes and modifications are to be understood as included within the scope of the present disclosure as defined by the appended claims unless they depart therefrom.

| | |
|---|---|
| 1 | circuit module |
| 20 | substrate |
| 20A | front surface |
| 24A | wiring electrode (wiring portion) |
| 31 | inductor |
| 32 | LNA (electronic component) |
| 33 | antenna switch (electronic component) |
| 40 | wire (conductive member) |
| 40A | one end portion (first portion) |
| 40B | other end portion (second portion) |
| 51 | sealing resin |
| 60 | shield film |
| 62 | side film |
| 62A | facing surface |
| 63 | side film |
| 63A | facing surface |
| 71 | imaginary straight line |
| 72 | winding axis |
| 81 | facing region |
| 82 | non-facing region |
| 83 | facing region |
| 84 | non-facing region |

What is claimed is:

1. A circuit module comprising:
a substrate;
an inductor mounted on a surface of the substrate;
a wiring portion provided on the surface of the substrate;
a sealing resin provided on the surface of the substrate and covering the inductor;
a conductive shield film covering at least a part of the sealing resin and including a side film extending in a direction intersecting the surface of the substrate; and
at least one conductive member disposed between the inductor and the side film on the surface of the substrate and electrically connected to the side film and the wiring portion, and wherein
a first portion of the conductive member is connected to a facing surface of the side film facing the inductor, wherein
a second portion of the conductive member is connected to the surface of the substrate, and wherein
in plan view in which the surface of the substrate is viewed along a direction orthogonal to the surface of the substrate, an imaginary straight line passing through the first portion and the second portion of the conductive member is inclined with respect to the facing surface of the side film.

2. The circuit module of claim 1, wherein
the conductive member is located away from the inductor in the plan view.

3. The circuit module of claim 1, wherein
the imaginary straight line is not orthogonal to a winding axis of the inductor.

4. The circuit module of claim 1, further comprising:
an electronic component mounted on the substrate and electrically connected to the inductor, and wherein
the electronic component is located on an opposite side of the conductive member with respect to the inductor in the plan view.

5. The circuit module of claim 1, wherein
the conductive member is a wire.

6. The circuit module of claim 1, wherein
the at least one conductive member comprises a plurality of conductive members, and wherein
in the plan view, the plurality of conductive members are arranged side by side along a direction in which the facing surface of the side film extends.

7. The circuit module of claim 6, wherein
the plurality of conductive members are arranged in parallel or substantially parallel to each other in the plan view.

8. The circuit module of claim 6, wherein
in a direction along the facing surface of the side film and parallel to the surface of the substrate, the second portion of one of two adjacent conductive members among the plurality of conductive members are located between the first portion and the second portion of another one of the two adjacent conductive members.

9. The circuit module of claim 6, wherein
the plurality of conductive members are disposed in a non-facing region not between the inductor and the side film on the surface of the substrate in addition to a facing region between the inductor and the side film on the surface of the substrate, and wherein
a distance between two adjacent conductive members among the plurality of conductive members in the facing region is shorter than a distance between the two adjacent conductive members in the non-facing region.

10. The circuit module of claim 2, wherein
the imaginary straight line is not orthogonal to a winding axis of the inductor.

11. The circuit module of claim 2, further comprising:
an electronic component mounted on the substrate and electrically connected to the inductor, and wherein
the electronic component is located on an opposite side of the conductive member with respect to the inductor in the plan view.

12. The circuit module of claim 2, wherein
the conductive member is a wire.

13. The circuit module of claim 2, wherein
the at least one conductive member comprises a plurality of conductive members, and wherein
in the plan view, the plurality of conductive members are arranged side by side along a direction in which the facing surface of the side film extends.
